(19) United States
(12) Patent Application Publication
(10) Pub. No.: US 2003/0218502 A1
(43) Pub. Date: Nov. 27, 2003

(54) Variable gain amplifier

(75) Inventors: Iain Ross MacTaggart, Eden Prairie, MN (US); Robert L. Rabe, Chanhassen, MN (US)

Correspondence Address: SCHWEGMAN, LUNDBERG, WOESSNER & KLUTH, P.A., P.O. BOX 2938, MINNEAPOLIS, MN, 55402, US

(73) Assignee: MathStar

(21) Appl. No.: 10/153,337

(22) Filed: May 22, 2002

(51) Int. Cl. H03F 3/45

(52) U.S. Cl. 330/254

(57) ABSTRACT

A variable gain amplifier is provided by including a gain control transistor with a differential amplifier. The differential amplifier has a first and second transistor each coupled to data inputs, which can receive a differential data signal. The gain control transistor is coupled between the drains of the first and second transistors. Control voltages are used to shunt differential current through the gain control transistor, providing variable gain with the maximum gain occurring when the control signals turn the gain control transistor off. A constant bias current is maintained by a pair of cascode transistors in parallel coupled to the sources of the first and second transistor.

### TECHNICAL FIELD

This document relates generally to amplifiers and particularly, but not by way of limitation, to variable gain stage amplifiers for equalizers.

### BACKGROUND

High-speed data transmission over a copper transmission medium incurs losses that can cause significant intersymbol interference. To compensate for these losses over a transmission medium, the signal from the transmission medium is processed through an equalizer prior to application to a receiver. In other instances, an equalizer is placed before a transmitter or between a transmitter and the transmission medium. Among other things, an equalizer is typically provided with a gain stage preceded by a high pass filter. The subsequent response of the system having a receiver preceded by an equalizer is a signal whose critical frequency, or cutoff frequency, is shifted to higher frequencies than for a receiver not preceded by an equalizer. However, this shift in critical frequency is often accompanied with a spiking, or peaking, in the frequency response just prior to the shifted critical frequency with a abrupt drop off at the critical frequency. This peaking in the frequency response causes errors in circuit stages and/or systems subsequent to the equalizer.

For these and other reasons there is a need for the present invention.

### BRIEF DESCRIPTION OF THE DRAWINGS

The drawings are offered by way of example, and not by way of limitation, and are not necessarily drawn to scale.

FIG. 1 shows an embodiment of an electronic device having a differential amplifier including a gain control, in accordance with the present invention.

FIG. 2 shows an embodiment of a variable gain differential amplifier as used in FIG. 1 with a transistor employed for the gain control of FIG. 1, in accordance with the present invention.

FIG. 2A shows a bias current control including two current sources coupled by a resistor, in accordance with the present invention.

FIG. 3 shows an block diagram of an embodiment of an equalizer including a filter, a first variable gain amplifier, a second variable gain amplifier, and a summing circuit, in accordance with the present invention.

FIG. 4A shows an embodiment of a communication apparatus including an equalizer and a receiver used in a transmission network, in accordance with the present invention.

FIG. 4B shows another embodiment of a communication apparatus used in a transmission network with equalizers associated with a transmitter.

### DETAILED DESCRIPTION

In the following detailed description, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that the embodiments may be combined, or that other embodiments may be utilized and that structural, logical and electrical changes may be made without departing from the spirit and scope of the present invention. The following detailed description is, therefore, not to be taken in a limiting sense, and the scope of the present invention is defined by the appended claims and their equivalents.

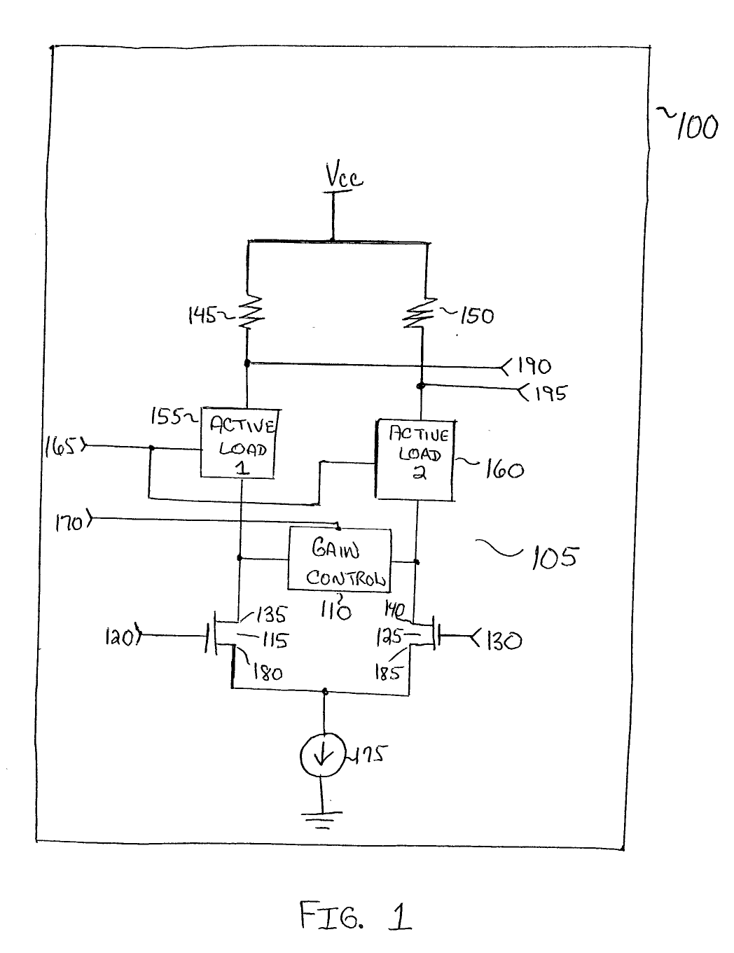

FIG. 1 shows an embodiment of an electronic device 100 having a differential amplifier 105 including a gain control 110, in accordance with the present invention. The electronic device 100 comprises, among other components, the differential amplifier 105 having a first transistor 115 coupled to a first data input 120 and a second transistor 125 coupled to a second data input 130. The gain control 110, coupled between a drain 135 of the first transistor 115 and a drain 140 of the second transistor 125, controls an effective transconductance of the differential amplifier 105.

The differential amplifier 105 of the electronic device 100 also includes load resistors 145, 150 coupled to a voltage source, Vcc, in series with a first active load 155 and a second active load 160, respectively. The first active load 155 is coupled to the drain 135 of the first transistor 115, while the second active load is coupled to the drain 140 of the second transistor 125. Both active loads are coupled to a first control voltage 165.

The first and second active loads 155, 160 operate in conjunction with the gain control 110, which is coupled to a second control voltage 170, to provide the variable gain of the amplifier for the electronic device 100. By varying the difference between the first control voltage 165 and the second control voltage 170, an amount of differential current through the gain control 110 can be regulated, where a bias current for the differential pair is held constant by the bias current control 175. In one embodiment, the gain provided is at a maximum when the gain control 110 is in an off state. This off state occurs when the second control voltage 170 is about 1V lower than the first control voltage 165. In other embodiments of the gain control 110, the off state occurs when the second control voltage 170 is less than a predetermined amount of voltage lower than the first control voltage 165. It can be appreciated by those skilled in the art that the roles of the first and second control voltages 165, 170 can be alternated based on the embodiment of the gain control and technology forming the basis for the differential amplifier.

Further, by coupling the gain control 110 between the drains 135, 140 of transistors 115, 125, respectively, a capacitive loading associated with coupling the gain control 110 to a source 180 of the first transistor 115 and to a source 185 of the second transistor 125 is avoided. Advantageously, this configuration allows for providing gain, while maintaining a substantially flat frequency response up to the frequency cutoff, or critical frequency, of the variable gain amplifier.

To further provide for a flat frequency response up to the frequency cutoff, the outputs of the differential amplifier 105 are isolated from the capacitance effects of the inputs of the first and second transistors 115, 225. This isolation is accomplished by coupling a first output 190 of the differential amplifier 105 to a node coupled to the resistor 145 and the first active load 155. Similarly, a second output 195 of the differential amplifier 105 is coupled to an node that is also coupled to the resistor 150 and the second active load 160.

Thus, the differential amplifier 105 coupled with the gain control 110 provides a variable gain amplifier with a substantially flat frequency response for the electronic device 100. In one embodiment, a data signal is applied to the first data input 120, and an inverted data signal (inverted with respect to the data signal applied to the first data input 120) is applied to the second data input 130. The first and second control voltages 165, 170 provide a gain that is variable where at the second output 195 a data output signal is provided, while at the first output 190 an inverted data output signal is provided.

Various embodiments of the electronic device 100 include, but are not limited to, a variable gain amplifier, integrated circuits incorporating a variable gain amplifier, equalizers used in communication apparatus, and electronic devices that use variable gain stages. It can be understood by those skilled in the art that the various embodiments of the electronic device 100 can incorporate one or more variable gain amplifiers in a cascade arrangement or in different stages of the electronic device, in accordance with the present invention. Such variable gain stages will be examined by discussing an embodiment of a variable gain amplifier in the following section.

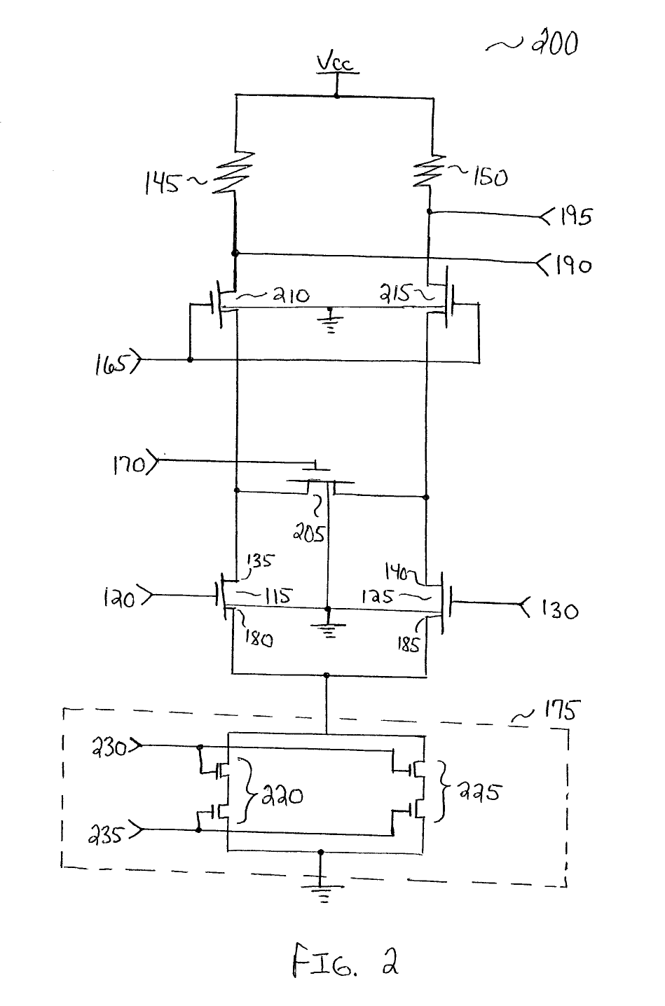

FIG. 2 shows an embodiment of a variable gain amplifier 200 as used in FIG. 1 with a transistor 205 employed for the gain control 110 of FIG. 1, in accordance with the present invention. The variable gain amplifier 200 is the differential amplifier 105 of FIG. 1 with a third transistor 205 employed as the gain control 110, a fourth transistor 210 employed as the first active load 155, and a fifth transistor 215 employed as the second active load 160. Further, the bias current control 175 comprises a pair of cascode transistors 220, 225 in parallel.

Without the third transistor 205 in the circuit, or network, of FIG. 2, the transistors 115, 125, 210, 215 and the resistors 145, 150 form a typical differential amplifier. All current passes directly to the load resistors 145, 150. The high-impedance bias current for the differential pairs is held constant during normal operation by the pair of cascode transistors 220, 225 coupled to the sources 180, 185 of transistors 115, 125, respectively.

Application of a differential input voltage to the first data input 120 and the second data input 130 produces a differential current between the first transistor 115 and the second transistor 125, resulting in a differential output voltage between resistors 145 and resistor 150. In linear operation, the magnitude of the differential output voltage is given by the relationship:

Vₒᵤₜ=Vᵢₙ*gₘ*R_{load}

where gₘ is the effective transconductance of transistors 115, 125, and R_{load} is the effective load resistance. Without the third transistor 205 in the network of FIG. 2, only a fixed gain is realizable.

The variable gain mechanism for the variable gain amplifier 200 is provided by the network comprising the transistors 205, 210, and 215. With the third transistor 205 in conduction, some of the differential current between the first transistor 115 and the second transistor 125 passes directly through the third transistor 205, avoiding the load resistors 145, 150. Passing some of the differential current through the third transistor 205 is the basic means of reducing the effective transconductance, and thereby adjusting the gain. The amount of current passing through the third transistor 205 is determined by the relative voltages of the first control voltage 165 and the second control voltage 170, where the control voltages are DC voltages.

The third transistor 205 is off when the second control voltage 170 is about 1V lower than the first control voltage 165. When the third transistor 205 is off, the variable gain amplifier 200 has its maximum gain. The third transistor 205 shunts increasingly more differential current as the second control voltage 170 is raised equal to and above the first control voltage 165, thereby reducing the gain. It can be appreciated by those skilled in the art that other technologies can be used, and that the third transistor 205, which is a gain transistor, can be implemented as a p channel transistor, in addition to being implemented as an n channel transistor. As a p channel transistor, the third transistor 205 is off when the second control voltage 170 is about 1V higher than the first control voltage 165.

Another configuration has employed a differential amplifier with a transistor coupling the differential pair as reported in Hartman, G. P. et al., “Continuous-time Adaptive-Analog Coaxial Cable Equalizer in 0.5 um CMOS,” ISCAS '99. Proceedings of the 1999 International Symposium on Circuits and Systems, vol. 2, 97-100, (May 30May-2, Jun. 1999). In the Hartman paper, a gain control transistor couples the sources of the transistors connected to the differential input data signals. By placing the gain control transistor at the sources of the transistors connected to the differential input data signals, a capacitive load is placed on the gain control transistor. This capacitive loading of the gain control transistor has been determined through simulation to result in a peak in the frequency response, especially at high frequencies. When used with a follow-on circuit (such as a receiver or subsequent stages of an equalizer) coupled to the output of the gain differential amplifier, this peaked frequency response causes a distortion in the follow-on circuit.

In the embodiments of the present invention, the gain control is coupled between the drains of the transistors (such as transistors 115, 125 of FIGS. 1, 2) coupled to the data signals, providing a substantially flat frequency response up to the critical frequency. For an embodiment of the variable gain amplifier 200, the gain-bandwidth characteristics are improved by using an optimized CMOS differential amplifier architecture with the addition of the third transistor 205 coupled between the drains 135, 140 of n-channel transistors 115, 125 respectively. For such a variable gain amplifier 200, a substantially flat frequency response with high critical frequency is attained due to several factors. First, the load of the gain control transistor (the third transistor 205) occurs on the sources of transistors 210, 215, which are very low impedance nodes, largely impervious to capacitive loading effects. Thus, by coupling the gain control transistor between the drains 135, 140 of transistors 115, 125, respectively, a capacitive loading associated with coupling a gain control to the source 180 of the first transistor 115 and to the source 185 of the second transistor 125 is avoided.

Additionally, the fourth and fifth transistors 210, 215 act as cascode devices to avoid the bandwidth-reducing effects of “Miller” capacitance between the data inputs 120, 130 and the outputs 190, 195 of the variable gain amplifier 200. This configuration isolates the outputs of the variable gain amplifier 200 from the capacitive effects of the inputs of the first and second transistors 115, 125.

Further, the variable gain amplifier 200 provides a gain control mechanism that is based on the difference of two signals: the first control voltage 165 and the second control voltage 170. This differential approach is robust because it is inherently insensitive to process variation, noise, and disturbances in ground and supply voltages.

Additionally, all the devices incorporated within the variable gain amplifier 200 can function at their optimal operating point due to the constant bias current provided by the bias current control 175. Functioning at an optimal operating point provides maximum bandwidth and fidelity. The bias current control 175 controls the bias current independent of the gain control mechanism, because the gain control transistor 205 conducts only differential current. Further, the bias control 175 also aids in maintaining a constant output common-mode voltage, which eases design constraints on subsequent circuit stages.

For the variable gain amplifier 200 of FIG. 2, the bias current control 175 comprises a pair of cascode transistors 220, 225 in parallel controlled by bias control voltages 230, 235. Alternately, the pair of cascode transistors 220, 225 can be replaced by one set of cascode transistors, cascode transistors 220 for instance. Further, the bias current control 175 can be realized using an ideal current source, that is, a current source that provides a constant current substantially independent of voltage.

In another embodiment of the teachings of the present invention, FIG. 2A shows a bias current control 240 including two current sources 245, 250 coupled by a resistor 255, in accordance with the present invention. The current source 245 is coupled both to resistor 255 and the source of transistor 115. Similarly, the current source 250 is coupled both to resistor 255 and the source of transistor 125. Further, the current sources 245, 250 can be realized as a cascode of transistors or as ideal current sources, as discussed above.

It can be further appreciated that other embodiments according to the teachings of the present invention can be realized. For instance, the use of MOSFET technology for the transistors of FIGS. 1 and 2 can be replaced with bipolar transistors, electronic tubes, and other technologies that can be used for differential amplifiers as is known to those skilled in the art. For instance, the differential amplifier and the gain control 110, 205 of FIGS. 1, 2, respectively, can be implemented using bipolar transistors, where the gain control is coupled between a collector of a bipolar transistor used as the first transistor 115 and a collector of another bipolar transistor used as the second transistor 125.

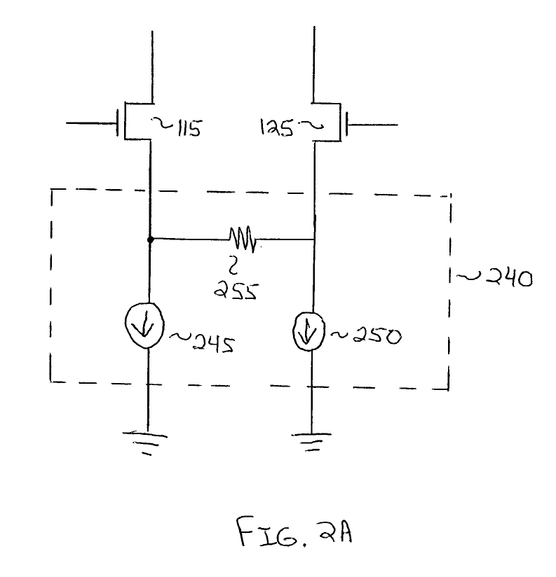

FIG. 3 shows an block diagram of an embodiment of an equalizer 300 including a filter 305, a first variable gain amplifier 310, a second variable gain amplifier 320, and a summing circuit 315, in accordance with the present invention. It can be appreciated by those skilled in the art that an equalizer can use other circuitry, but the elements shown in FIG. 3 are simplified to focus discussion on an embodiment of the present invention. The equalizer 300 can be constructed using the variable gain amplifier 200 of FIG. 2 as the variable gain amplifiers 310, 320 with a filter 305 providing data signals to the input of the variable gain amplifier 310. However, the gain control for the variable gain amplifiers 310, 320 are not limited to a single gain control transistor. Other gain control mechanisms configured as in FIG. 1 can be employed that control the effective transconductance of the first and second transistors 115, 125 with little or no capacitance loading, and isolate the outputs of the variable gain amplifier from the capacitive effects of the data inputs 120, 130.

A signal is provided to a input of the filter 305 and to an input of the second variable gain amplifier 320. The output of the filter 305, which is typically a high pass filter, is input to the first variable gain amplifier 310. As a result, the output of the first variable gain variable 310 provides a filtered component of the signal received by the equalizer 300. Further, the output of the second variable gain amplifier 320 provides an unfiltered component of the signal received by the equalizer 300. The filtered component of the signal and the unfiltered component of the signal are input to the summing circuit 315. By summing a filtered and an unfiltered component of the signal provided by the variable gain amplifiers 310, 320, respectively, a mechanism is created to adjust the frequency response of equalizer 300.

The output data signal from the summing circuit 315 is provided to the subsequent stages of the equalizer 300. The filter 305, the variable gain amplifiers 310, 320, and the summing circuit 315 can be fabricated as an integrated circuit or as an integrated circuit chip set, including various semiconductor embodiments of resistors, transistors, and other electronic components, according to processes known to those skilled in the art.

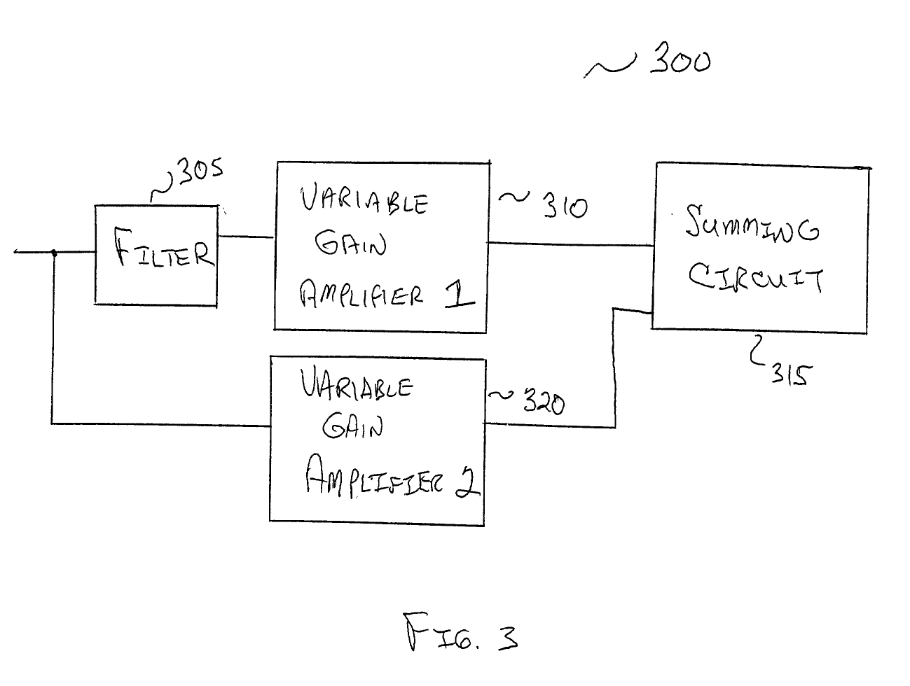

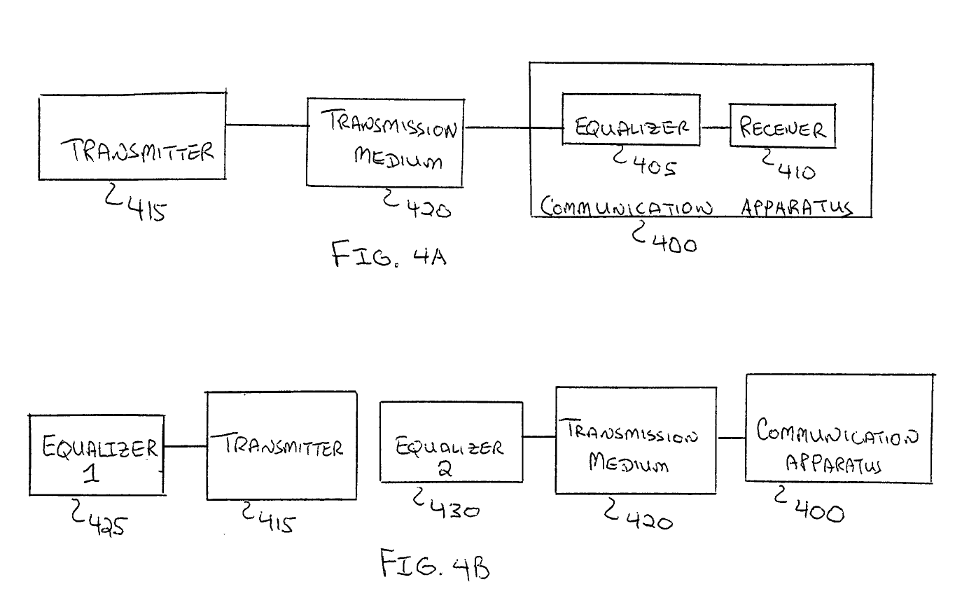

FIG. 4A shows an embodiment of a communication apparatus 400 including an equalizer 405 and a receiver 410 used in a transmission network, in accordance with the present invention. It can be appreciated by those skilled in the art that a communication apparatus contains other elements and circuitry, but the elements shown in FIG. 4 are simplified to focus discussion on an embodiment of the present invention. A data signal is sent from a transmitter 415 over a transmission medium 420 to a communication apparatus 400. Typically, the transmission medium 420 is lossy, and the data signal transmitted along the transmission medium must essentially be reshaped by the equalizer 405 before inputting the data signal into the receiver 410. The equalizer 405 comprises the elements of the equalizer 300, including a variable gain amplifier formed in an embodiment of the present invention.

FIG. 4B shows another embodiment of a communication apparatus 400 used in a transmission network with equalizers associated with a transmitter 415. In one embodiment, a first equalizer 425 is placed in a signal path before transmitter 415. In another embodiment, a second equalizer 430 is placed in a signal path between the transmitter 415 and a transmission medium 420 in the transmission network. Alternately, both the first equalizer 425 and the second equalizer 430 can be placed in the path of the signal in the transmission network. The signal is conveyed from a transmitting end to a receiving end of the transmission network to a communication apparatus 400, as in FIG. 4A. However, with an equalizer at the transmitting end of the transmission network, the communication apparatus can be realized with or without equalizer 405.

It is to be understood that the above description is intended to be illustrative, and not restrictive. For example, the above-discussed embodiments may be used in combination with each other. Many other embodiments will be apparent to those of skill in the art upon reviewing the above description. The scope of the invention should, therefore, be determined with reference to the appended claims, along with the full scope of equivalents to which such claims are entitled. In the appended claims, the terms “first,” “second,” “third,” etc. are used merely as labels, and are not intended to impose numeric requirements on their objects.

What is claimed is:

1. An electronic device comprising
a differential amplifier having a first transistor coupled to a first data input and a second transistor coupled to a second data input;
a gain control for controlling an effective transconductance of the differential amplifier, the gain control coupled between a drain of the first transistor and a drain of the second transistor.

2. The electronic device of claim 1, wherein the differential amplifier and the gain control are implemented using bipolar transistors, the gain control coupled between a collector of the first transistor and a collector of the second transistor.

3. The electronic device of claim 1, further comprising:
a first active load coupled to the drain of the first transistor, the first active load coupled to a first control voltage; and
a second active load coupled to the drain of the second transistor, the second active load coupled to the first control voltage, wherein a first output of the differential amplifier coupled to the first active load and a second output of the differential amplifier coupled to the second active load are isolated from the capacitive effects of the first and second transistors.

4. The electronic device of claim 3, wherein the gain control is coupled to a second control voltage.

5. An electronic device comprising
a differential amplifier having a first transistor coupled to a first data input and a second transistor coupled to a second data input;
a third transistor for controlling an effective transconductance of the differential amplifier, the third transistor coupled between a drain of the first transistor and a drain of the second transistor.

6. The electronic device of claim 5, further comprising:
a fourth transistor having a source serially coupled to the drain of the first transistor, a gate of the fourth transistor coupled to a first control voltage; and
a fifth transistor having a source serially coupled to the drain of the second transistor, a gate of the fifth transistor coupled to the first control voltage, wherein a first output of the differential amplifier is coupled to a drain of the fourth transistor and a second output of the differential amplifier is coupled to a drain of the fifth transistor.

7. The electronic device of claim 6, wherein a gate of the third transistor is coupled to a second control voltage.

8. The electronic device of claim 5, wherein a source of the first transistor is coupled to a bias current control, and a source of the second transistor is coupled to the bias current control.

9. A variable gain amplifier comprising:
a differential amplifier having a first transistor coupled to a first data input and a second transistor coupled to a second data input; and
a gain control for controlling an effective transconductance of the differential amplifier, the gain control coupled between a drain of the first transistor and a drain of the second transistor.

10. The variable gain amplifier of claim 9, further comprising:
a first active load serially coupled to the drain of the first transistor, the first active load coupled to a first control voltage; and
a second active load serially coupled to the drain of the second transistor, the second active load coupled to the first control voltage, wherein a first output of the differential amplifier coupled to the first active load and a second output of the differential amplifier coupled to the second active load are isolated from the capacitive effects of the first and second transistors.

11. The variable gain amplifier of claim 10, wherein the gain control is coupled to a second control voltage.

12. The variable gain amplifier of claim 11, wherein the gain control is in an off state when the second control voltage is less than or equal to a predetermined voltage lower than the first control voltage.

13. The variable gain amplifier of claim 11, wherein the gain control is in an off state when the first control voltage is less than or equal to a predetermined voltage lower than the second control voltage.

14. The variable gain amplifier of claim 9, wherein a source of the first transistor is coupled to a bias current control, and a source of the second transistor is coupled to the bias current control.

15. The variable gain amplifier of claim 9, wherein a source of the first transistor is coupled to a first bias current control, and a source of the second transistor is coupled to a second bias current control.

16. The variable gain amplifier of claim 15, wherein the bias current control is controlled by a pair of cascode active devices in parallel.

17. The variable gain amplifier of claim 14, wherein the bias current control is controlled by cascode active devices.

18. The variable gain amplifier of claim 14, wherein the bias current control is controlled by an ideal current source.

19. A variable gain amplifier comprising:
a differential amplifier having a first transistor coupled to a first data input and a second transistor coupled to a second data input; and
a third transistor coupled between a drain of the first transistor and a drain of the second transistor.

20. The variable gain amplifier of claim 19, further comprising:
a fourth transistor having a source serially coupled to the drain of the first transistor, a gate of the fourth transistor coupled to a first control voltage; and
a fifth transistor having a source serially coupled to the drain of the second transistor, a gate of the fifth transistor coupled to the first control voltage, wherein a first output of the differential amplifier is coupled to a drain of the fourth transistor and a second output of the differential amplifier is coupled to a drain of the fifth transistor.

21. The variable gain amplifier of claim 19, wherein a gate of the third transistor is coupled to a second control voltage.

22. The variable gain amplifier of claim 20, wherein the third transistor is in an off state when the second control voltage is about 1 V lower than the first control voltage.

23. The variable gain amplifier of claim 19, wherein a source of the first transistor is coupled to a bias current control, and a source of the second transistor is coupled to the bias current control.

24. The variable gain amplifier of claim 23, wherein the bias current control is controlled by a pair of cascode active devices in parallel.

25. The variable gain amplifier of claim 23, wherein the bias current control is controlled by cascode active devices.

26. The variable gain amplifier of claim 23, wherein the bias current control is controlled by an ideal current source.

27. An equalizer having a variable gain stage comprising
an summing circuit; and
a variable gain amplifier coupled to the summing circuit, the variable gain amplifier comprising:
a differential amplifier having a first transistor coupled to a first data input and a second transistor coupled to a second data input; and
a gain control for controlling an effective transconductance of the differential amplifier, the gain control coupled between a drain of the first transistor and a drain of the second transistor.

28. The equalizer of claim 27, further comprising:
a first active load coupled to the drain of the first transistor, the first active load coupled to a first control voltage; and
a second active load coupled to the drain of the second transistor, the second active load coupled to the first control voltage, wherein a first output of the differential amplifier coupled to the first active load and a second output of the differential amplifier coupled to the second active load are isolated from the capacitive effects of the first and second transistors.

29. The equalizer of claim 28, wherein the gain control is coupled to a second control voltage.

30. The equalizer of claim 28, further comprising a filter coupled to the input of the variable gain amplifier.

31. The equalizer of claim 30, further comprising a second variable gain amplifier coupled to the summing circuit.

32. An equalizer having a variable gain stage comprising
an summing circuit; and
a variable gain amplifier coupled to the summing circuit, the variable gain amplifier comprising:
a differential amplifier having a first transistor coupled to a first data input and a second transistor coupled to a second data input; and
a third transistor coupled between a drain of the first transistor and a drain of the second transistor.

33. The equalizer of claim 32, further comprising:
a fourth transistor having a source serially coupled to the drain of the first transistor, a gate of the fourth transistor coupled to a first control voltage; and
a fifth transistor having a source serially coupled to the drain of the second transistor, a gate of the fifth transistor coupled to the first control voltage, wherein a first output of the differential amplifier coupled to a drain of the fourth transistor and a second output of the differential amplifier coupled to a drain of the fifth transistor.

34. The equalizer of claim 33, wherein a gate of the third transistor is coupled to a second control voltage.

35. The equalizer of claim 32, further comprising a filter coupled to the input of the variable gain amplifier.

36. The equalizer of claim 32, further comprising a second variable gain amplifier coupled to the summing circuit.

37. The equalizer of claim 32, wherein a source of the first transistor is coupled to a bias current control, and a source of the second transistor is coupled to the bias current control.

38. The equalizer of claim 37, wherein the bias current control is controlled by a pair of cascode active devices in parallel.

39. An integrated circuit comprising:
a differential amplifier having a first transistor coupled to a first data input and a second transistor coupled to a second data input; and
a gain control for controlling an effective transconductance of the differential amplifier, the gain control coupled between a drain of the first transistor and a drain of the second transistor.

40. The integrated circuit of claim 39, further comprising:
a first active load serially coupled to the drain of the first transistor, the first active load coupled to a first control voltage; and
a second active load serially coupled to the drain of the second transistor, the second active load coupled to the first control voltage, wherein a first output of the differential amplifier coupled to the first active load and a second output of the differential amplifier coupled to the second active load are isolated from the capacitive effects of the first and second transistors.

41. The integrated circuit of claim 40, wherein the gain control is coupled to a second control voltage.

42. The integrated circuit of claim 41, wherein the gain control is in an off state when the second control voltage is less than or about equal to a predetermined voltage lower than the first control voltage.

43. The variable gain amplifier of claim 39, wherein a source of the first transistor is coupled to a bias current control, and a source of the second transistor is coupled to the bias current control.

44. The variable gain amplifier of claim 43, wherein the bias current control is controlled by a pair of cascode active devices in parallel.

45. An integrated circuit comprising:
a differential amplifier having a first transistor coupled to a first data input and a second transistor coupled to a second data input; and
a third transistor coupled between a drain of the first transistor and a drain of the second transistor.

46. The integrated circuit of claim 45, further comprising:
a fourth transistor having a source serially coupled to the drain of the first transistor, a gate of the fourth transistor coupled to a first control voltage; and
a fifth transistor having a source serially coupled to the drain of the second transistor, a gate of the fifth transistor coupled to the first control voltage, wherein a first output of the differential amplifier is coupled to a drain of the fourth transistor and a second output of the differential amplifier is coupled to a drain of the fifth transistor.

47. The integrated circuit of claim 46, wherein a gate of the third transistor is coupled to a second control voltage.

48. The integrated circuit of claim 47, wherein the third transistor is in an off state when the second control voltage is about 1 V lower than the first control voltage.

49. The integrated circuit of claim 45, wherein a source of the first transistor is coupled to a bias current control, and a source of the second transistor is coupled to the bias current control.

50. The integrated circuit of claim 49, wherein the bias current control is controlled by a pair of cascode active devices in parallel.

51. The integrated circuit of claim 49, wherein the bias current control is controlled by cascode active devices.

52. The integrated circuit of claim 49, wherein the bias current control is controlled by an ideal current source.

53. A data communication apparatus comprising
a receiver for receiving a data signal; and
an equalizer coupled to the receiver, the equalizer comprising:
a differential amplifier having a first transistor coupled to a first data input and a second transistor coupled to a second data input; and
a gain control for controlling an effective transconductance of the differential amplifier, the gain control coupled between a drain of the first transistor and a drain of the second transistor.

54. The data communication apparatus of claim 53, further comprising:
a first active load coupled to the drain of the first transistor, the first active load coupled to a first control voltage; and
a second active load coupled to the drain of the second transistor, the second active load coupled to the first control voltage, wherein a first output of the differential amplifier coupled to the first active load and a second output of the differential amplifier coupled to the second active load are isolated from the capacitive effects of the first and second transistors.

55. The data communication apparatus of claim 54, wherein the gain control is coupled to a second control voltage.

56. The data communication apparatus of claim 53, wherein the equalizer further comprises a filter coupled to an input of the differential amplifier.

57. An data communication apparatus comprising
a receiver for receiving a data signal; and
an equalizer coupled to the receiver, the equalizer comprising:
a differential amplifier having a first transistor coupled to a first data input and a second transistor coupled to a second data input; and
a third transistor coupled between a drain of the first transistor and a drain of the second transistor.

58. The data communication apparatus of claim 57, further comprising:
a fourth transistor having a source serially coupled to the drain of the first transistor, a gate of the fourth transistor coupled to a first control voltage; and
a fifth transistor having a source serially coupled to the drain of the second transistor, a gate of the fifth transistor coupled to the first control voltage, wherein a first output of the differential amplifier is coupled to a drain of the fourth transistor and a second output of the differential amplifier is coupled to a drain of the fifth transistor.

59. The data communication apparatus of claim 58, wherein a gate of the third transistor is coupled to a second control voltage.

60. The data communication apparatus of claim 57, wherein a source of the first transistor is coupled to a bias current control, and a source of the second transistor is coupled to the bias current control.

61. The data communication apparatus of claim 60, wherein the constant bias current is controlled by a pair of cascode active devices in parallel.

62. The data communication apparatus of claim 57, wherein the equalizer further comprises a filter coupled to an input of the differential amplifier.
